(19) United States
(12) Patent Application Publication
(10) Pub. No.: US 2002/0139416 A1
(43) Pub. Date: Oct. 3, 2002

(54) Multi-element polycrystal for solar cells and method of manufacuturing the same

(76) Inventors: Kazuo Nakajima, Kurokawa-gun (JP); Noritaka Usami, Sendai-shi (JP); Kozo Fujiwara, Sendai-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 10/105,391

(22) Filed: Mar. 26, 2002

(30) Foreign Application Priority Data
Mar. 27, 2001 (JP) 2001-090713

(51) Int. Cl. H01L 31/00

(52) U.S. Cl. 136/258; 438/97

(57) ABSTRACT

The present invention provides a multi-element polycrystal having a non-uniform microscopic distribution of the elements, by cooling a melt containing a plurality of elements at a controlled cooling rate. The present invention further provides a polycrystal for use in a solar cell capable of absorbing sunlight more efficiently at low cost, a solar cell using the polycrystal and methods of forming the polycrystal and the solar cell.

### CROSS-REFERENCE TO RELATED APPLICATIONS

This application is based upon and claims the benefit of priority from the prior Japanese Patent Application No. 2001-090713, filed Mar. 27, 2001, the entire contents of which are incorporated herein by reference.

### BACKGROUND OF THE INVENTION

1. Field of the Invention

The present invention relates to a polycrystal for use in a solar cell, formed of a plurality of elements such as Si—Ge or In—Ga—As, and a method of manufacturing the same.

2. Description of the Related Art

As a method for manufacturing a polycrystal for use in a practical solar cell at low cost, a cast method (a kind of solidification method) is known. Although an Si polycrystal can be formed at low cost by the cast method, the light-absorption efficiency of the Si polycrystal thus obtained is low. This is because the Si polycrystal does not absorb sunlight in a long-wavelength range of the spectrum. On the other hand, a tandem-form solar cell is known to be excellent in light-absorption efficiency. Such a tandem-form solar cell has a hetero structure comprising a thin-film compound semiconductor stacked on an Si or Ge substrate. However, the manufacturing cost of the tandem-form solar cell is high since the thin film is formed by epitaxial growth.

Thus, a polycrystal for a solar cell satisfying both conditions of high light-absorption efficiency and low cost has not yet been obtained. In the solar cell manufacturing process presently performed, a polycrystal is appropriately chosen depending upon the use of the solar cell to be manufactured. However, in recent years, as the desire to use sunlight as a clean energy source has grown, the demand for developing a solar cell with high conversion efficiency and capable of efficiently absorbing sunlight at low cost has increased.

### BRIEF SUMMARY OF THE INVENTION

An object of the present invention is to provide a polycrystal for a solar cell capable of efficiently absorbing sunlight at low cost, a method of forming the polycrystal, and a solar cell obtained by this method.

The present invention provides the followings:

(1) A multi-element polycrystal for use in a solar cell, having a non-uniform microscopic distribution of elements.

(2) A multi-element polycrystal for use in a solar cell, in which the multi-element polycrystal is essentially composed of elements A and B different in absorption-wavelength region and having an average composition represented by A_{1-M}B_{M}, where M takes a predetermined value greater than 0 but less than 1, and having a composition represented by A_{1-X}B_{X} where X takes any value of 0≦X≦1 when compositions of a plurality of spots are measured within any region of the polycrystal.

(3) A polycrystal according to item (2) being composed of two elements, Si and Ge.

(4) A multi-element polycrystal for use in a solar cell, in which the multi-element polycrystal is essentially composed of compound elements CE and DE different in absorption-wavelength region and having an average composition represented by C_{1-N}D_{N}E, where N takes predetermined value greater than 0 but less than 1, and having a composition represented by C_{1-X}D_{X}E where X takes any value of 0≦X≦1, when compositions of a plurality of spots are measured within any region of the polycrystal.

(5) A polycrystal according to item (4) being composed of three elements, In, Ga and As.

(6) A solar cell comprising a multi-element polycrystal having a non-uniform microscopic distribution of elements.

(7) A solar cell according to item (6) in which the multi-element polycrystal is essentially composed of elements A and B different in absorption-wavelength region and having an average composition represented by A_{1-M}B_{M}, where M takes a predetermined value greater than 0 but less than 1, and having a composition represented by A_{1-X}B_{X} where X takes any value of 0≦X≦1 when compositions of a plurality of spots are measured within any region of the polycrystal.

(8) A multi-element polycrystal according to item (7) being composed of two elements, Si and Ge.

(9) A multi-element polycrystal according to item (6) being a mixed crystal essentially composed of compound elements CE and DE different in absorption-wavelength region and having an average composition represented by C_{1-N}D_{N}E, where N takes predetermined value greater than 0 but less than 1, and having a composition represented by C_{1-X}D_{X}E where X takes any value of 0≦X≦1, when compositions of a plurality of spots are measured within any region of the polycrystal.

(10) A multi-element polycrystal according to item (9) being composed of three elements, In, Ga and As.

(11) A method of forming a multi-element polycrystal for use in a solar cell comprising the steps of:

preparing a melt containing a plurality of elements; and

forming a multi-element polycrystal having a non-uniform microscopic distribution of the plurality of elements.

(12) A method of forming a multi-element polycrystal for use in a solar cell comprising the steps of: preparing a melt essentially containing elements A and B different in absorption-wavelength region, and having an average composition represented by A_{1-M}B_{M}, where M takes a predetermined value greater than 0 but less than 1; and forming a desired microscopic distribution by controlling a cooling rate.

(13) A method of forming a multi-element polycrystal for use in a solar cell comprising the steps of: preparing a melt essentially containing compound elements CE and DE different in absorption-wavelength region, and having an average composition represented by C_{1-N}D_{N}E, where N takes predetermined value greater than 0 but less than 1; and forming a desired microscopic distribution by controlling a cooling rate.

The term “microscopic distribution” used in the claims and the specification refers to a distribution of elements within a crystal area (having a typical size of from several microns to several millimeters). The phrase “non-uniform microscopic distribution” means that X takes any value 0≦X≦1 as measured at any given point within each crystal area. The preferable value of M or N and preferable microscopic distribution may be appropriately set in accordance with the types of raw materials and characteristics required for a solar cell and the use of the solar cell.

The polycrystal according to the present invention has uniform macroscopic distribution. The phrase “uniform macroscopic distribution” means that the average value of X at any area takes substantially the same value as that measured at any other area. In other words, the composition at any given area within the crystal corresponds to a pre-designed one.

The distribution of elements is most preferably designed so as to absorb sunlight effectively, thereby converting light energy into electrical energy at the most efficient conversion rate possible.

“Controlling a cooling rate” is performed to obtain a desired non-uniform microscopic distribution of elements in a crystal. The value of X may be appropriately set in accordance with the types of raw materials and characteristics required for a solar cell and the use of the solar cell.

According to the present invention, it is possible to obtain a desired distribution of elements in a crystal to absorb sunlight most sensitively and high conversion efficiently by using a simple and practical crystal growing method, such as a cast method, under controlled cooling conditions (e.g., controlling the cooling rate and a super-cooling rate) and controlled composition of a melt. The present invention further attains a polycrystal for use in a solar cell capable of efficiently absorbing sunlight, and a solar cell using the polycrystal. If this method is employed, a solar cell having a desired distribution of elements, which allows sunlight to be absorbed more efficiently, can be obtained without use of a complicated structure such as a tandem structure. This method can be applied not only to an Si—Ge crystal but also to a multi-element polycrystal such as an In_{1-X}Ga_{X}As crystal. In this sense, the practicality of the method of the present invention is high.

### BRIEF DESCRIPTION OF THE SEVERAL VIEWS OF THE DRAWING

FIGS. 1A, 1B, 1C and 1D are histograms of the content of the Si element of Si—Ge polycrystals which are grown from a melt at different cooling rates, showing the microscopic distribution of the Si element within a crystal area (the cooling rate of FIG. 1A is 0.5° C./min, the cooling rate of FIG. 1B is 10° C./min, FIG. 1C is a case of air cooling and FIG. 1D is a case of water cooling);

FIGS. 2A, 2B, 2C and 2D are photomicrographs of Si—Ge polycrystals corresponding to FIGS. 1A, 1B, 1C and 1D, respectively; and

FIG. 3 shows the dependency of a short-circuit photo-current on a wavelength with respect to a solar cell of an Si_{0.5}Ge_{0.5} crystal (conventional case) having a uniform composition, and a solar cell of an Si—Ge polycrystal (the present invention) having a different microscopic distribution of the Si element as shown in FIG. 1B, where R means a distribution of the total composition of a crystal represented by Si_{1-X}Ge_{X} (0.0≦X≦1.0) and R=1:1:1:1:1:1:1:1:1:1:1 means the ratio of the following compositions: Si_{0.0}Ge_{1.0}, Si_{0.1}Ge_{0.9}, Si_{0.2}Ge_{0.8}, . . . Si_{0.8}Ge_{0.2}, Si_{0.9}Ge_{0.1}, and Si_{1.0}Ge_{0.0}, which are obtained by microscopically measuring the crystal at different points within the crystal. The note “d=2 μm” at the upper right refers to the diffusion distance of the carrier used in calculation.

### DETAILED DESCRIPTION OF THE INVENTION

### EXAMPLE

Now, an example of the present invention will be explained.

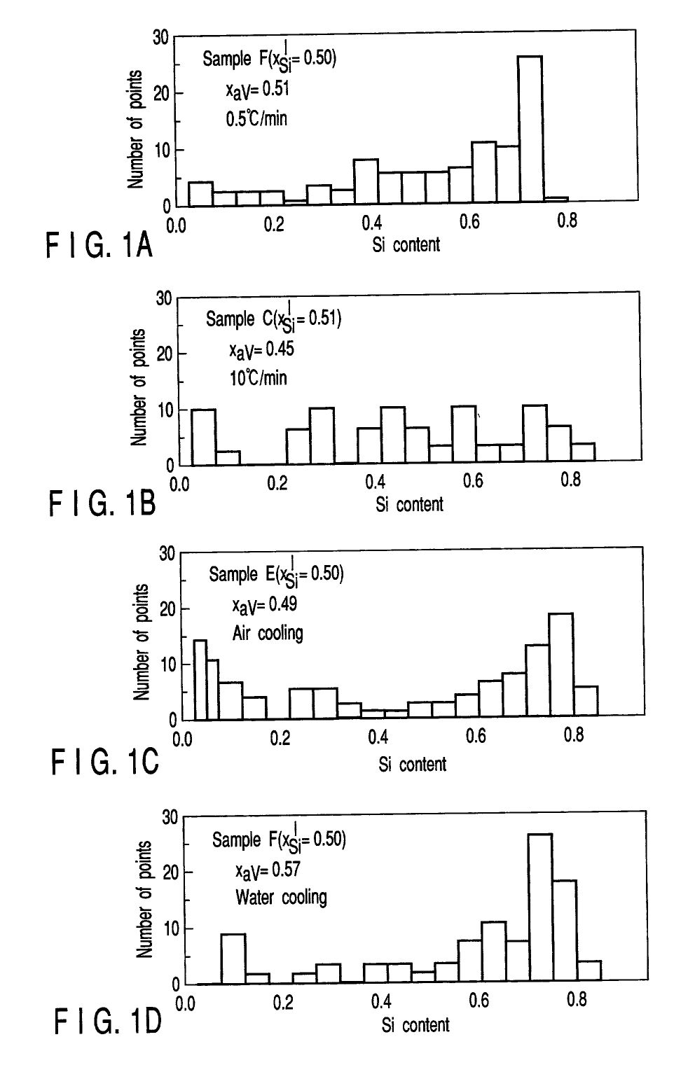

Si raw material (1.66 g) and Ge raw material (3.71 g) were mixed and allowed to melt, thereby preparing a melt containing Si and Ge in the same ratio (50/50). The melt was allowed to grow through solidification while cooling it at a cooling rate of 10° C./min to obtain a polycrystal. The microscopic distribution of an Si element of the polycrystal thus obtained was almost the same as that shown in FIG. 1B.

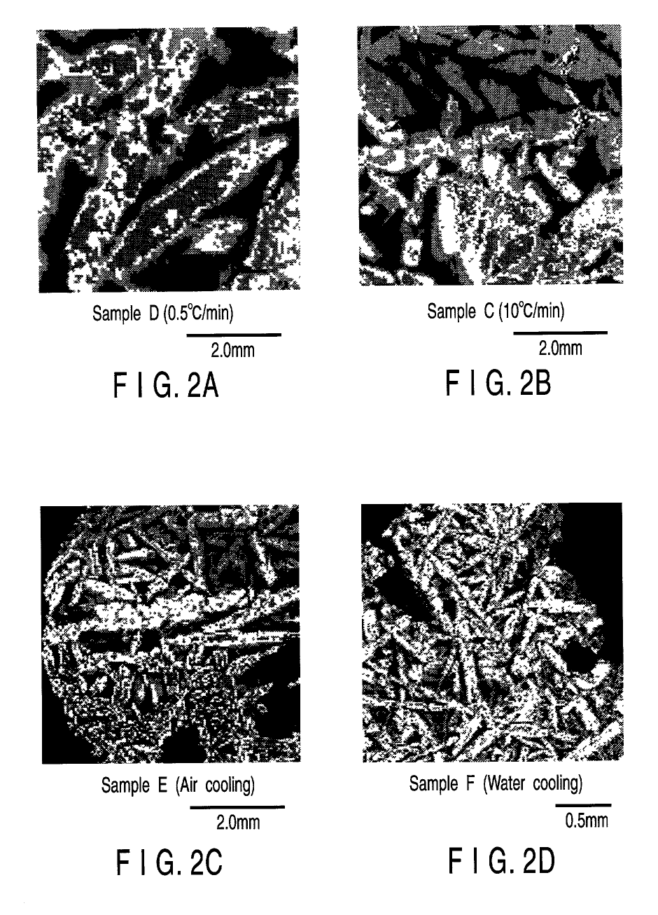

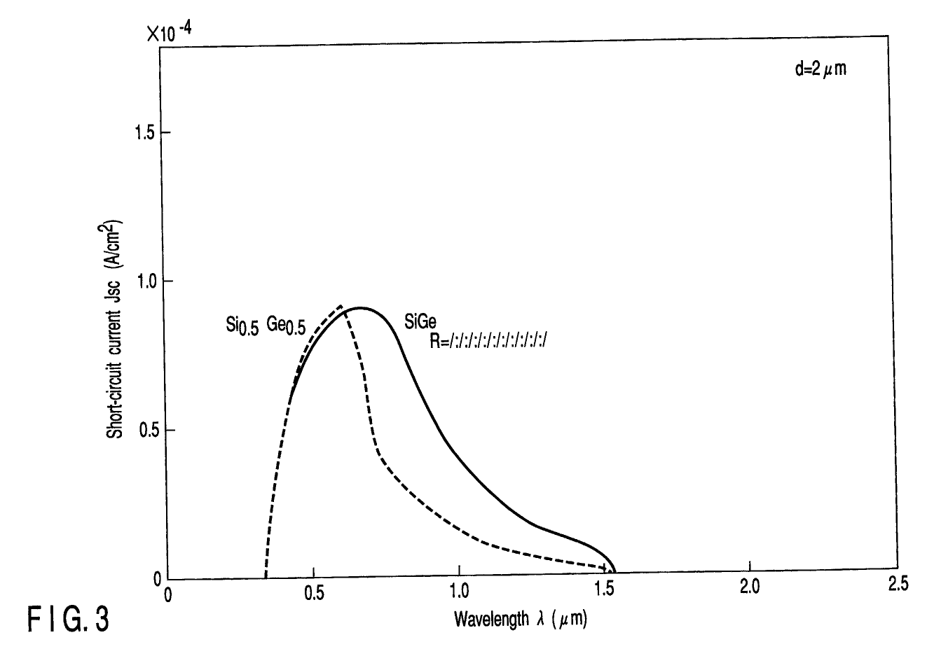

Each of figures of FIGS. 1A-1D shows a histogram showing a distribution of an Si element. The horizontal axis shows the content of the Si element. The vertical axis shows the number of measuring points having the same content of the Si element. Various microscopic distributions of an Si element are obtained by changing the cooling rate as shown in FIGS. 1A, 1B, 1C and 1D. The textures of the obtained crystals differ depending upon the cooling rate, as shown in FIGS. 2A-2D. FIG. 3 shows the dependency of the short-circuit currents upon the wavelength with respect to a conventional solar cell and a solar cell of the present invention. The conventional solar cell employs an Si_{0.5}Ge_{0.5} crystal uniform in composition (the microscopic distribution of elements does not differ). The solar cell of the present invention employs an Si_{1-X}Ge_{X} polycrystal whose microscopic distribution of elements differs as shown in FIGS. 2A-2D. The Si_{0.5}Ge_{0.5} crystal is formed by the conventional liquid-phase epitaxy or multicomponent zone melting method.

As is apparent from FIG. 3, the area surrounded by the short-circuit current curve of the present invention (microscopic distribution of these elements differs, even if an average ratio of Si:Ge=1:1) is larger than that of the conventional Si_{0.5}Ge_{0.5} crystal (distribution of elements is uniform). This means that the total current value obtained by the present invention is larger than that obtained by the conventional crystal. The crystal of the present invention is therefore demonstrated to be more effective in absorbing light that the conventional crystal.

Furthermore, to obtain a more efficient solar cell, a thin film may be deposited on the Si—Ge polycrystal of the present invention serving as a substrate to construct a two-layered structure.

Although an Si_{1-X}Ge_{X} based polycrystal is described in this embodiment, a more efficient polycrystal can be obtained if an In_{1-X}Ga_{X}As-based polycrystal is used. As materials for such a polycrystal, three elements such as a GaAs_{1-X}Sb_{X} (III-V group) and four elements such as In_{1-X}Ga_{X}P_{1-Y}Sb_{Y} may be used. In short, any polycrystal may be employed in the present invention as long as it is formed of materials different in absorption-wavelength range.

As is demonstrated in FIG. 3, a short-circuit current can be obtained depending upon a wavelength range of absorption of the sunlight spectrum by the Si_{1-X}Ge_{X} polycrystal solar cell of the present invention. The current value obtained by the present invention is larger than that obtained by the conventional Si_{1-X}Ge_{X} polycrystal solar cell under the same conditions.

Furthermore, the microscopic distribution of elements of the Si_{1-X}Ge_{X} polycrystal is changed by controlling a cooling rate (as shown in FIGS. 1A-1D), thereby controlling the sensitivity of the Si_{1-X}Ge_{X} polycrystal to wavelengths of the sunlight spectrum (as shown in FIG. 3). It is therefore possible to obtain a polycrystal having a desired distribution of elements, thereby attaining a solar cell capable of efficiently absorbing sunlight.

What is claimed is:

1. A multi-element polycrystal for use in a solar cell, having a non-uniform microscopic distribution of elements.

2. A multi-element polycrystal for use in a solar cell, wherein said multi-element polycrystal is essentially composed of elements A and B different in absorption-wavelength region and having an average composition represented by A_{1-M}B_{M}, where M takes a predetermined value greater than 0 but less than 1, and having a composition represented by A_{1-X}B_{X} where X takes any value of 0≦X≦1 when compositions of a plurality of spots are measured within any region of said polycrystal.

3. A polycrystal according to claim 2 being composed of two elements, Si and Ge.

4. A multi-element polycrystal for use in a solar cell, wherein said multi-element polycrystal is essentially composed of compound elements CE and DE different in absorption-wavelength region and having an average composition represented by C_{1-N}D_{N}E, where N takes predetermined value greater than 0 but less than 1, and having a composition represented by C_{1-X}D_{X}E where X takes any value of 0≦X≦1, when compositions of a plurality of spots are measured within any region of said polycrystal.

5. A polycrystal according to claim 4 being composed of three elements, In, Ga and As.

6. A solar cell comprising a multi-element polycrystal having a non-uniform microscopic distribution of elements.

7. A solar cell according to claim 6, in which a multi-element polycrystal is essentially composed of elements A and B different in absorption-wavelength region and having an average composition represented by A_{1-M}B_{M}, where M takes a predetermined value greater than 0 but less than 1, and having a composition represented by A_{1-X}B_{X} where X takes any value of 0≦X≦1 when compositions of a plurality of spots are measured within any region of said polycrystal.

8. A solar cell according to claim 7, wherein said multi-element polycrystal is composed of two elements, Si and Ge.

9. A solar cell according to claim 6, in which a multi-element polycrystal is essentially composed of compound elements CE and DE different in absorption-wavelength region and having an average composition represented by C_{1-N}D_{N}E, where N takes predetermined value greater than 0 but less than 1, and having a composition represented by C_{1-X}D_{X}E where X takes any value of 0≦X≦1, when compositions of a plurality of spots are measured within any region of said polycrystal.

10. A solar cell according to claim 9, wherein said multi-element polycrystal is composed of three elements, In, Ga and As.

11. A method of forming a multi-element polycrystal for use in a solar cell comprising the steps of:
preparing a melt containing a plurality of elements; and
forming a multi-element polycrystal having a non-uniform microscopic distribution of said plurality of elements.

12. A method of forming a multi-element polycrystal for use in a solar cell comprising the steps of: preparing a melt essentially containing elements A and B different in absorption-wavelength region, and having an average composition represented by A_{1-M}B_{M}, where M takes a predetermined value greater than 0 but less than 1; and forming a desired microscopic distribution by controlling a cooling rate.

13. A method of forming a multi-element polycrystal for use in a solar cell comprising the steps of: preparing a melt essentially containing compound elements CE and DE different in absorption-wavelength region, and having an average composition represented by C_{1-N}D_{N}E, where N takes predetermined value greater than 0 but less than 1; and forming a desired microscopic distribution by controlling a cooling rate.
